(19) United States
(12) Patent Application Publication
(10) Pub. No.: US 2015/0183327 A1
(43) Pub. Date: Jul. 2, 2015

(54) APPARATUS AND METHOD FOR CONTROLLING POWER GENERATION TYPE SOLAR SHUTTER

(71) Applicant: ELECTRONICS AND TELECOMMUNICATIONS RESEARCH INSTITUTE, Daejeon-city (KR)

(72) Inventors: Eun-Ryung LEE, Daegu (KR); Sang-Ho LEE, Daegu (KR); Kee-Koo KWON, Daegu (KR); Soo-In LEE, Daejeon (KR)

(21) Appl. No.: 14/580,464

(22) Filed: Dec. 23, 2014

(30) Foreign Application Priority Data
Jan. 2, 2014 (KR) 10-2014-0000311

(51) Int. Cl. B60L 11/18; H01L 31/049; H01L 31/0468

(52) U.S. Cl. CPC B60L 11/1809; H01L 31/0468; H01L 31/049

(57) ABSTRACT

Disclosed herein is an apparatus and method for controlling a power generation type solar shutter, including: storing a control condition and an operation corresponding to the control condition; detecting that an event occurs; and if the event satisfies the control condition, controlling the solar shutter that performs a charging function for a vehicle based on the operation corresponding to the control condition, wherein the control condition includes at least one selected from the group consisting of: humidity, rain, snow, light, a driving state, the remaining battery charge, seasons, latitude, and a usage level of a heater and/or an air conditioner.

### CROSS REFERENCE TO RELATED APPLICATION(S)

This application claims the benefit of Korean Patent Application No. 10-2014-0000311, filed Jan. 2, 2014, which is hereby incorporated by reference in its entirety into this application.

### BACKGROUND OF THE INVENTION

1. Technical Field

The present invention relates generally to an apparatus and method for controlling a power generation type solar shutter and, more particularly, to an apparatus and method for controlling a power generation type solar shutter for a vehicle.

2. Description of the Related Art

As well known to those skilled in the art, solar energy or wind power generation is mainly used in charging methods for various electric machines and devices including electric vehicles. In particular, in a charging method using solar energy among these charging methods, a power generation type solar shutter disposed on a vehicle is used.

However, when the power generation type solar shutter for the vehicle according to the related art is used, the state of the vehicle or a charging state of the battery therein is not considered, therefore charging efficiency is not high.

Thus, an apparatus and method for efficiently charging a vehicle by operating a power generation type solar shutter in consideration of the state of the vehicle or a charging state of the battery therein are required.

### PRIOR-ART DOCUMENT

### Patent Document

(Patent document 1) Prior-art document 1: Korean Patent Application Publication No. 10-2010-0126077 (entitled Sunroof for Vehicle)

### SUMMARY OF THE INVENTION

Accordingly, the present invention has been made keeping in mind the above problems occurring in the prior art, and an object of the present invention is to provide an apparatus and method for controlling a power generation type solar shutter, whereby the power generation type solar shutter is operated in consideration of the environment around a vehicle, a state of the vehicle or a charging state of the battery therein.

In order to accomplish the above object, the present invention provides a method for controlling a power generation type solar shutter, including: storing a control condition and an operation corresponding to the control condition; detecting that an event occurs; and if the event satisfies the control condition, controlling the solar shutter that performs a charging function for a vehicle based on the operation corresponding to the control condition, wherein the control condition may include at least one selected from the group consisting of: humidity, rain, snow, light, a driving state, the remaining battery charge, seasons, latitude, and a usage level of a heater and/or an air conditioner.

The solar shutter that performs a charging function may be at least one selected from the group consisting of: a front window solar shutter, a rear window solar shutter, side window solar shutters, and a sunroof solar shutter.

If a control condition regarding humidity, that is, humidity around the vehicle, is equal to or greater than power-generation limiting humidity, an operation corresponding to the control condition regarding humidity may include not unfolding the solar shutter, and if a control condition regarding humidity, that is, humidity around the vehicle, is less than the power generation limiting humidity, an operation corresponding to the control condition regarding humidity may include unfolding part or the entirety of the solar shutter.

If a control condition regarding rain or snow, that is, an intensity of rain or snow or the quantity of rain or snow is equal to or greater than a predetermined value, an operation corresponding to the control condition regarding rain or snow may include not unfolding the solar shutter, and if a control condition regarding rain or snow, that is, an intensity of rain or snow or the quantity of rain or snow is less than a predetermined value, an operation corresponding to the control condition regarding rain or snow may include unfolding part or the entirety of the solar shutter.

If a control condition regarding light, that is, illuminance around the vehicle is equal to or greater than power generation limiting illuminance, an operation corresponding to the control condition regarding light may include unfolding part or the entirety of the solar shutter, and if a control condition regarding light, that is, illuminance around the vehicle is less than the power generation limiting illuminance, an operation corresponding to the control condition regarding light may include not unfolding the solar shutter.

If a control condition regarding a driving state is a fully-parked state in which starting of the vehicle is stopped and it is determined that a driver is in the vehicle or a parked state in which starting of the vehicle is stopped and it is determined that the driver is outside the vehicle, an operation corresponding to the control condition may include fully unfolding the solar shutter, and if a control condition regarding a driving state is a temporarily-parked state in which starting of the vehicle is performed and the vehicle does not operate and it is determined that the driver is in the vehicle or a driving state, an operation corresponding to the control condition may include unfolding only part of the solar shutter.

In order to accomplish the above object, the present invention also provides an apparatus for controlling a power generation type solar shutter, including: a solar shutter unit including at least one solar shutter that performs a charging function for a vehicle; a storage unit in which a control condition and an operation corresponding to the control condition are stored; and a controller detecting that an event occurs, wherein, if the controller determines whether the event satisfies the control condition and it is determined that the event satisfies the control condition, the controller may control the solar shutter that charges the vehicle to be unfolded based on the operation corresponding to the control condition, and the control condition may include at least one selected from the group consisting of humidity, rain, snow, light, a driving state, the remaining battery charge, seasons, latitude, and a usage level of a heater and/or an air conditioner.

The solar shutter unit may include at least one selected from the group consisting of a front window solar shutter, a rear window solar shutter, side window solar shutters, and a sunroof solar shutter.

Each solar shutter of the solar shutter unit may include an on/off button, and a solar shutter including an on/off button in an off state may not be controlled by the controller even if the event satisfies the control condition.

The apparatus may further include a hygrometer that detects humidity around the vehicle, wherein, if a control condition regarding humidity, that is, humidity around the vehicle is equal to or greater than power generation limiting humidity, an operation corresponding to the control condition regarding humidity may include not unfolding the solar shutter, and if a control condition regarding humidity, that is, humidity around the vehicle is less than the power generation limiting humidity, an operation corresponding to the control condition regarding humidity may include unfolding part or the entirety of the solar shutter.

The apparatus may further include a rainsplash sensor that detects an intensity of rain or snow or the quantity of rain or snow, wherein the controller may determine whether the event satisfies the control condition based on the intensity of rain or snow or the quantity of rain or snow, and if a control condition regarding rain or snow, that is, the intensity of rain or snow or the quantity of rain or snow is equal to or greater than a predetermined value, an operation corresponding to the control condition regarding rain or snow may include not unfolding the solar shutter, and if a control condition regarding rain or snow, that is, the intensity of rain or snow or the quantity of rain or snow is less than a predetermined value, an operation corresponding to the control condition regarding rain or snow may include unfolding part or the entirety of the solar shutter.

The apparatus may further include an illuminance sensor that detects illuminance around the vehicle, wherein the controller may determine whether the event satisfies the control condition based on illuminance detected by the illuminance sensor, and if a control condition regarding light, that is, illuminance around the vehicle is equal to or greater than power generation limiting illuminance, an operation corresponding to the control condition regarding light may include unfolding part or the entirety of the solar shutter, and if a control condition regarding light, that is, illuminance around the vehicle is less than the power generation limiting illuminance, an operation corresponding to the control condition regarding light may include not unfolding the solar shutter.

If the controller determines whether the event satisfies the control condition regarding light and illuminance detected for a predetermined amount of time is maintained to be less than the power generation limiting illuminance, the controller may control the solar shutter to not be unfolded.

The controller may detect a usage level of a heater and/or an air conditioner and may determine whether the event satisfies the control condition, and if a control condition regarding a usage level of the heater and/or air conditioner is increased to be equal to or greater than a predetermined setting value, an operation corresponding to the control condition may include unfolding part or the entirety of the solar shutter.

The apparatus may further include a driving state sensor that detects a driving state of the vehicle, wherein the controller may determine whether the event satisfies the control condition based on the driving state detected by the driving state sensor, and if a control condition regarding the driving state is a fully-parked state in which starting of the vehicle is stopped and it is determined that a driver is in the vehicle or a parked state in which starting of the vehicle is stopped and it is determined that the driver is outside the vehicle, an operation corresponding to the control condition may include fully unfolding the solar shutter, and if a control condition regarding the driving state is a temporarily-parked state in which starting of the vehicle is performed and the vehicle does not operate and it is determined that the driver is in the vehicle or a driving state, an operation corresponding to the control condition may include unfolding only part of the solar shutter.

If the driving state sensor detects that the vehicle is in the driving state, the controller may control the front window solar shutter to not be fully unfolded, regardless of whether the event satisfies the control condition.

If the driving state sensor detects that the vehicle is being reversed, the controller may control the rear window solar shutter to not be fully unfolded, regardless of whether the event satisfies the control condition.

If the driving state sensor detects that the vehicle is being reversed or in the driving state, the controller may control the side window solar shutters to not be unfolded, regardless of whether the event satisfies the control condition.

The apparatus may further include a battery charging state sensor that detects the remaining battery charge of the vehicle, wherein the controller may determine whether the event satisfies the control condition, based on the remaining battery charge of the vehicle detected by the battery charging state sensor, and if a control condition regarding the remaining battery charge of the vehicle, is equal to or greater than a maximally-charged limit, an operation corresponding to the control condition regarding the remaining battery charge of the vehicle may include controlling the at least one solar shutter to not be unfolded or controlling only part of the shutter to be unfolded, and if a control condition regarding the remaining battery charge of the vehicle is less than the maximally-charged limit, an operation corresponding to the control condition regarding the remaining battery charge of the vehicle may include controlling at least one solar shutter to be unfolded.

The controller may control each solar shutter of the solar shutter unit regardless of whether the event satisfies the control condition.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram of an apparatus for controlling a power generation type solar shutter according to an embodiment of the present invention;

FIG. 2 is a block diagram of a solar shutter unit of the apparatus illustrated in FIG. 1;

FIG. 3 is a view of a place in which solar shutters are disposed, of the apparatus of FIG. 1;

FIG. 4 is a block diagram of a sensor unit of the apparatus of FIG. 1;

FIG. 5 is a flowchart illustrating a method for controlling a power generation type solar shutter according to an embodiment of the present invention;

FIG. 6 is a view of a case where a front window solar shutter is not unfolded, of the apparatus of FIG. 1;

FIG. 7 is a view of a case where the front window solar shutter is fully unfolded, of the apparatus of FIG. 1; and

FIG. 8 is a view of a case where only part of the front window solar shutter is unfolded, of the apparatus of FIG. 1.

### DESCRIPTION OF THE PREFERRED EMBODIMENTS

Embodiments of the present invention are described with reference to the accompanying drawings in order to describe the present invention in detail so that those having ordinary knowledge in the technical field to which the present invention pertains can easily practice the present invention. However, the present invention may be embodied in several different forms and is not limited to embodiments described herein. In the drawings, in order to clearly describe the present invention, unrelated portions with the description will be omitted, and similar reference numerals are used to designate similar elements throughout the specification.

It will be understood that, in the specification and the claims, when a portion “comprises” and/or “includes” an element, it may not exclude another element but may further include another element unless there is a specially opposed description.

It will also be understood that, in the specification, when a portion is “connected” to another portion, it may be “directly connected” to another element or “electrically coupled” to another element in a configuration in which intervening elements are present.

An apparatus and method for controlling a power generation type solar shutter according to embodiments of the present invention will now be described in detail with reference to the accompanying drawings.

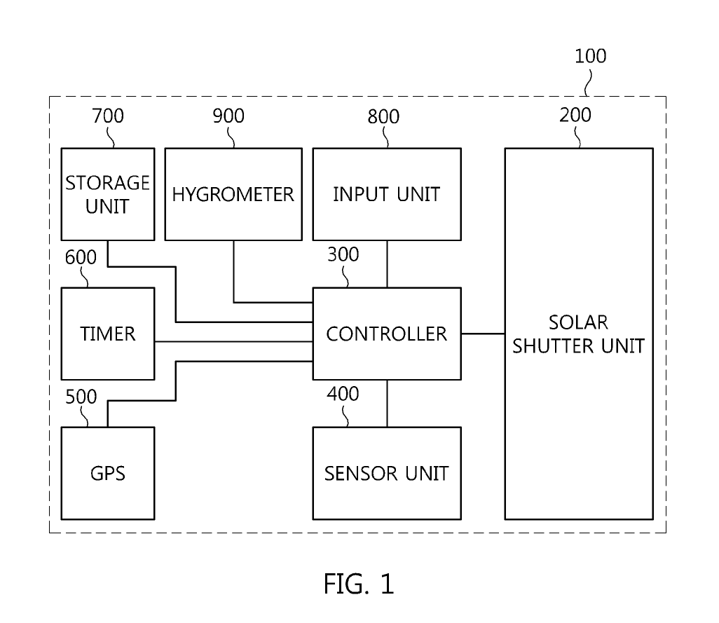

First, an apparatus for controlling a power generation type solar shutter according to an embodiment of the present invention will be described in detail with reference to FIGS. 1 through 4.

FIG. 1 is a block diagram of an apparatus for controlling a power generation type solar shutter according to an embodiment of the present invention.

An apparatus 100 for controlling a power generation type solar shutter according to the current embodiment of the present invention includes a solar shutter unit 200, a controller 300, a sensor unit 400, a global positioning system (GPS) 500, a timer 600, a storage unit 700, an input unit 800, and a hygrometer 900. However, embodiments illustrated in FIG. 1 are not essential and thus, the apparatus 100 for controlling the power generation type solar shutter having more or less elements than those of FIG. 1 may also be implemented.

Next, each configuration of the apparatus 100 for controlling the power generation type solar shutter of FIG. 1 will be described.

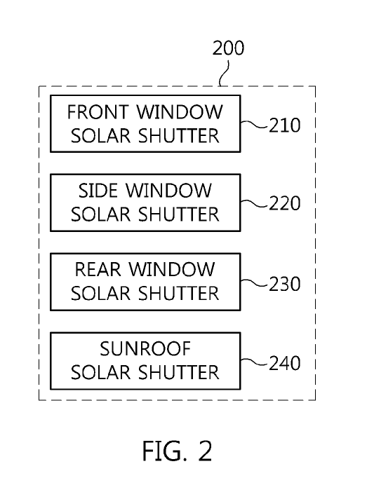

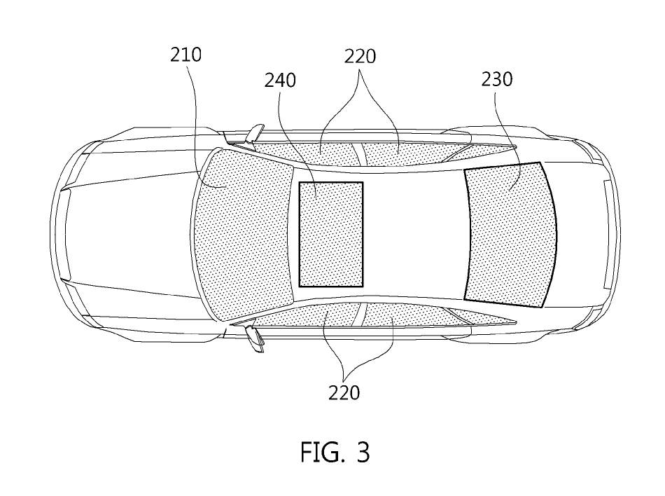

First, the solar shutter unit 200 of the apparatus 100 illustrated in FIG. 1 will be described with reference to FIGS. 2 and 3.

FIG. 2 is a block diagram of the solar shutter unit 200 of the apparatus 100 illustrated in FIG. 1.

The solar shutter unit 200 of the apparatus 100 of FIG. 1 includes a front window solar shutter 210, side window solar shutters 220, a rear window solar shutter 230, and a sunroof solar shutter 240. However, elements illustrated in FIG. 2 are not essential and thus, the solar shutter unit 200 having more or less elements than those of FIG. 2 may also be implemented.

Each of the solar shutters 210, 220, 230, and 240 of the apparatus 1 of FIG. 1 may convert solar light into electrical energy and may generate power for power generation. Also, each of the solar shutters 210, 220, 230, and 240 is selectively unfolded when a vehicle is parked or driven, thereby serving as a sun shade and simultaneously performing a function of a power generator that converts solar light into electrical energy.

Each of the solar shutters 210, 220, 230, and 240 of the apparatus 100 of FIG. 1 may be electrically connected to a vehicle battery by connecting lead wires that output the generated power and may charge the vehicle battery or may be electrically connected to various accessories, such as an air cleaner, a navigation device, and seat heating wires, and may serve as an auxiliary power supply. That is, each of the solar shutters 210, 220, 230, and 240 of the apparatus 100 of FIG. 1 is a power generation type solar shutter that generates power in the vehicle and vehicle accessories.

Each of the solar shutters 210, 220, 230, and 240 of the apparatus 100 of FIG. 1 may include an on/off button (not shown). According to the current embodiment of the present invention, each of the solar shutters 210, 220, 230, and 240 of the apparatus 100 of FIG. 1 that includes the on/off button (not shown) in an on state operates in response to control of the controller 300 when a control condition is satisfied. Each of the solar shutters 210, 220, 230, and 240 of the apparatus 100 of FIG. 1 that includes the on/off button (not shown) in an off state does not operate in response to control of the controller 300 when the control condition is satisfied. FIG. 3 is a view of a place in which solar shutters are disposed, of the apparatus 100 of FIG. 1.

Referring to FIG. 3, the front window solar shutter 210 of the apparatus 100 of FIG. 1 is disposed on a front window of the vehicle.

The side window solar shutters 220 of the apparatus 100 of FIG. 1 are disposed on side windows of the vehicle.

The rear window solar shutter 230 of the apparatus 100 of FIG. 1 is disposed on a rear window of the vehicle.

The sunroof solar shutter 240 of the apparatus 100 of FIG. 1 is disposed on a sunroof of the vehicle.

Subsequently, each configuration of the apparatus 100 for controlling the power generation type solar shutter of FIG. 1 will be described.

The controller 300 controls an overall operation of the apparatus 100 for controlling the power generation type solar shutter of FIG. 1. The controller 300 of the apparatus 100 of FIG. 1 controls each of the solar shutters 210, 220, 230, and 240 of the solar shutter unit 200 using the sensor unit 400, the GPS 500 or the timer 600. In particular, the controller 300 of the apparatus 100 of FIG. 1 controls opening/closing of the solar shutters 210, 220, 230, and 240 based on an operation corresponding to the control condition when the control condition is generated. According to the current embodiment of the present invention, the controller 300 may individually control the solar shutters 210, 220, 230, and 240. Also, the controller 300 of the apparatus 100 of FIG. 1 may also control each of the solar shutters 210, 220, 230, and 240 regardless of whether the control condition is satisfied. That is, the controller 300 of the apparatus 100 of FIG. 1 may control opening/closing of the solar shutters 210, 220, 230, and 240 regardless of whether the control condition is satisfied.

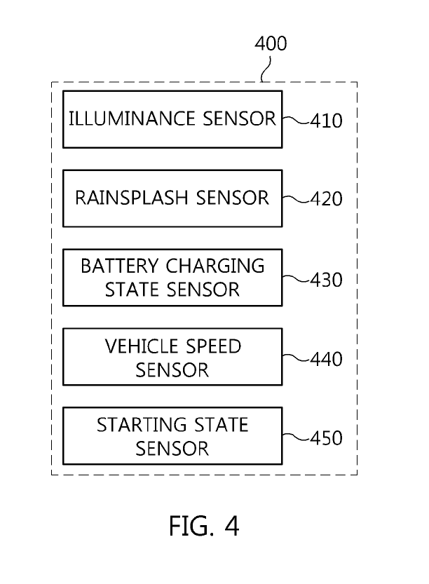

FIG. 4 is a block diagram of the sensor unit 400 of the apparatus 100 of FIG. 1.

The sensor unit 400 of the apparatus 100 of FIG. 1 includes an illuminance sensor 410, a rainsplash sensor 420, a battery charging state sensor 430, a vehicle speed sensor 440, and a starting state sensor 450. However, elements illustrated in FIG. 4 are not essential and thus, the sensor unit 400 having more or less elements than those of FIG. 4 may also be implemented.

The illuminance sensor 410 detects illuminance around the vehicle. In other words, the illuminance sensor 410 of the apparatus 100 of FIG. 1 detects the quantity or brightness of light around the vehicle. According to the current embodiment of the present invention, the controller 300 determines brightness of light around the vehicle using the illuminance sensor 410.

The rainsplash sensor 420 detects the intensity of rain or snow or the quantity of rain or snow around the vehicle.

The battery charging state sensor 430 detects a degree of charging the battery of the vehicle. The controller 300 of the apparatus 100 of FIG. 1 determines a charging state of the vehicle using the battery charging state sensor 430.

The vehicle speed sensor 440 detects a speed of the vehicle. The controller 300 of the apparatus 100 of FIG. 1 determines the speed of the vehicle using the vehicle speed sensor 440.

The starting state sensor 450 detects whether the vehicle is started. The controller 300 of the apparatus 100 of FIG. 1 determines whether the vehicle is started, using the starting state sensor 450.

However, according to another embodiment of the present invention, each of the illuminance sensor 410, the rainsplash sensor 420, the battery charging state sensor 430, the vehicle speed sensor 440, and the starting state sensor 450 may be omitted. In this case, information obtained by each of the illuminance sensor 410, the rainsplash sensor 420, the battery charging state sensor 430, the vehicle speed sensor 440, and the starting state sensor 450 may also be obtained by an electronic control unit (ECU) or another unit within the vehicle.

Each configuration of the apparatus 100 for controlling the power generation type solar shutter of FIG. 1 will be described again.

The GPS 500 of the apparatus 100 of FIG. 1 may measure an accurate time and an accurate distance from three or more satellites and may calculate an accurate current position with respect to three different distances using trigonometry. Also, the GPS 500 of the apparatus 100 of FIG. 1 may use a method of obtaining distance and time information from three satellites and correcting the distance and time information using one satellite.

Also, the GPS 500 of the apparatus 100 of FIG. 1 may obtain latitudinal and longitudinal positions and the accurate time together with three-dimensional (3D) speed information. Also, the GPS 500 may provide date information. However, according to another embodiment of the present invention, the GPS 500 may be omitted. In this case, the latitudinal and longitudinal positions, the 3D speed information, and the time information may also be obtained using the ECU or another unit within the vehicle.

The timer 600 of the apparatus 100 of FIG. 1 provides date and time information. The controller 300 may obtain time information from the timer 600.

The storage unit 700 may include at least one type of storage medium selected from the group consisting of a flash memory type, a hard disk type, a multimedia card micro type, a card type memory, such as secure digital (SD) or extreme digital (XD) memory, random access memory (RAM), static random access memory (SRAM), read only memory (ROM), electrically erasable programmable read-only memory (EEPROM), programmable read-only memory (PROM), magnetic memory, a magnetic disk, and an optical disk. The apparatus 100 for controlling the power generation type solar shutter may operate in association with a web storage that performs a storing function of the storage unit 700 on the Internet.

The control condition input by the input unit 800 and an operation corresponding to the control condition may be stored in the storage unit 700.

Also, the storage unit 700 of the apparatus 100 of FIG. 1 may store a program for the operation of the controller 300 or may temporarily store pieces of input/output data.

The input unit 800 of the apparatus 100 of FIG. 1 may include at least one among a touch screen, a button, a keyboard, and a mouse. The controller 300 may receive user input from the input unit 800. According to the current embodiment of the present invention, the input unit 800 may receive a control condition and an operation corresponding to the control condition through the user input.

The hygrometer 900 of the apparatus 100 of FIG. 1 detects humidity around the vehicle.

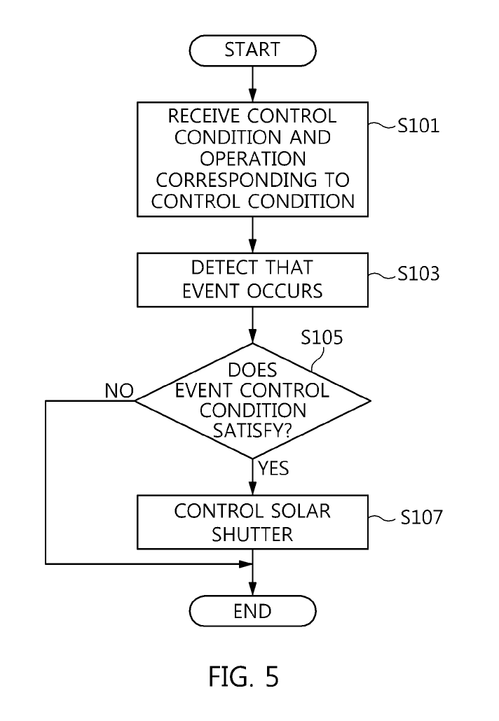

Next, a method for controlling a power generation type solar shutter according to an embodiment of the present invention will be described with reference to FIGS. 5 through 8.

FIG. 5 is a flowchart illustrating a method for controlling a power generation type solar shutter according to an embodiment of the present invention.

The input unit 800 receives a control condition and an operation corresponding to the control condition from a user input (Operation S101).

The control condition and the operation corresponding to the control condition according to the current embodiment of the present invention may also be stored in the storage unit 700. The control condition according to the current embodiment of the present invention may include a control condition regarding humidity, rain, snow, light, a driving state, the remaining battery charge, seasons, latitude, or a usage level of a heater and/or air-conditioner.

If a control condition regarding rain or snow, i.e., the intensity of rain or snow or the quantity of rain or snow detected by the rainsplash sensor 420 is equal to or greater than a predetermined value, an operation corresponding to the control condition may include a case where the controller 300 does not unfold the solar shutters 210, 220, 230, and 240.

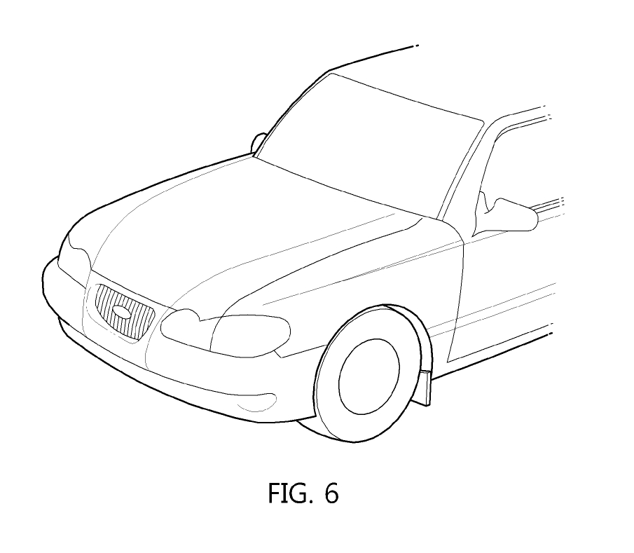

FIG. 6 is a view of a case where the front window solar shutter 210 is not unfolded, of the apparatus 100 of FIG. 1.

As illustrated in FIG. 6, the front window solar shutter 210 may not be unfolded. When the front window solar shutter 210 of the apparatus 100 of FIG. 1 is not unfolded, the front window of the vehicle may not be shielded. In FIG. 6, the front window solar shutter 210 is just an example, and the present invention may also be applied to the other solar shutters 220, 230, and 240 than the front window solar shutter 210.

According to the current embodiment of the present invention, charging efficiency of the solar shutters 210, 220, 230, and 240 may be lowest when they are not unfolded.

If the control condition regarding rain or snow, i.e., the intensity of rain or snow or the quantity of rain or snow detected by the rainsplash sensor 420 is less than the predetermined value, an operation corresponding to the control condition may include controlling the solar shutters 210, 220, 230, and 240 to be fully unfolded, by using the controller 300. According to the current embodiment of the present invention, even in this case, the controller 300 may control the solar shutters 210, 220, 230, and 240 so that only part of the front window solar shutter 210 may be unfolded, so as to obtain a driver's field of vision during driving. According to the current embodiment of the present invention, the side window solar shutters 220 may not be unfolded so that side mirrors may be used.

Also, even in this case, if the vehicle is being reversed, the controller 300 may not unfold the rear window solar shutter 230 so as to obtain the driver's field of vision during driving. According to the current embodiment of the present invention, the side window solar shutters 220 may not be unfolded so that the side mirrors may be used.

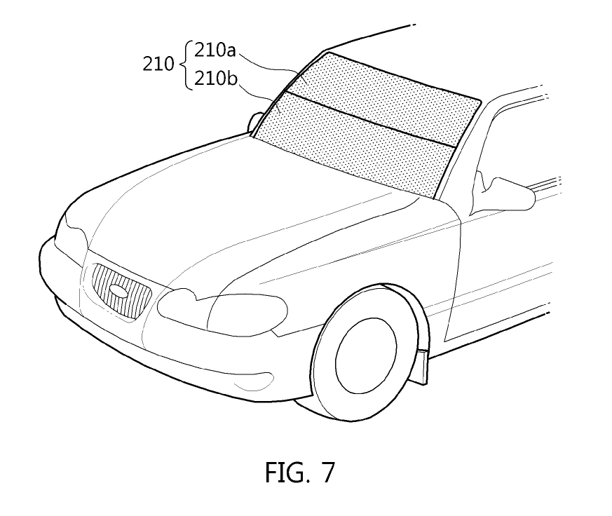

FIG. 7 is a view of a case where the front window solar shutter 210 is fully unfolded, of the apparatus 100 of FIG. 1.

As illustrated in FIG. 7, the front window solar shutter 210 may be fully unfolded. When the front window solar shutter 210 of the solar shutter unit 200 of the apparatus 100 of FIG. 1 is fully unfolded, the front window of the vehicle may be fully shielded. The front window solar shutter 210 of the solar shutter unit 200 of the apparatus 100 of FIG. 1 includes an upper solar shutter 210a and a lower solar shutter 210b. When the front window solar shutter 210 is fully unfolded, the controller 300 controls the front window solar shutter 210 so that the upper solar shutter 210a of the front window solar shutter 210 may unfolded to gradually shield a lower portion of the front window of the vehicle from an upper portion of the front window of the vehicle. Also, in this case, the controller 300 controls the front window solar shutter 210 so that the lower solar shutter 210b of the front window solar shutter 210 may be unfolded to gradually the upper portion of the front window of the vehicle to the upper portion of the front window of the vehicle. This may also apply to a case where only part of the front window solar shutter 210 is unfolded.

According to another embodiment of the present invention, the front window solar shutter 210 may include only one of the upper solar shutter 210a and the lower solar shutter 210b. When the front window solar shutter 210 includes only the upper solar shutter 210a and the front window solar shutter 210 is fully unfolded, the controller 300 controls the front window solar shutter 210 so that the upper solar shutter 210a of the front window solar shutter 210 may be unfolded to gradually shield the lower portion of the front window of the vehicle from the upper portion of the front window of the vehicle. Also, when the front window solar shutter 210 includes only the lower solar shutter 210b, the controller 300 controls the front window solar shutter 210 so that the lower solar shutter 210b of the front window solar shutter 210 may be unfolded to gradually shield the upper portion of the front window of the vehicle from the lower portion of the front window of the vehicle. This may also apply to a case where only part of the front window solar shutter 210 is unfolded.

In FIG. 7, the front window solar shutter 210 has been described as an example. However, the present invention may also apply to the other solar shutters 220, 230, and 240 instead of the front window solar shutter 210.

According to the current embodiment of the present invention, charging efficiency of the solar shutters 210, 220, 230, and 240 may be highest when they are fully unfolded.

If the control condition regarding rain or snow, i.e., the intensity of rain or snow or the quantity of rain or snow detected by the rainsplash sensor 420 is equal to or greater than the predetermined value, an operation corresponding to the control condition may include controlling only part of the solar shutters 210, 220, 230, and 240 to be unfolded, by using the controller 300.

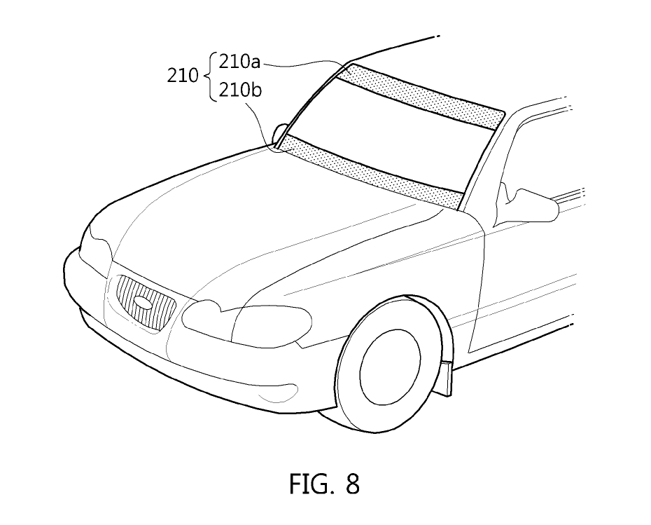

FIG. 8 is a view of a case where only part of the front window solar shutter 210 is unfolded, of the apparatus of FIG. 1.

As illustrated in FIG. 8, only part of the front window solar shutter 210 may be unfolded.

When only part of the front window solar shutter 210 of the solar shutter unit 200 of the apparatus 100 of FIG. 1 is unfolded, only part of the front window of the vehicle may be shielded. In FIG. 8, the front window solar shutter 210 has been described as an example. However, the present invention may also apply to the other solar shutters 220, 230, and 240 instead of the front window solar shutter 210.

According to the current embodiment of the present invention, charging efficiency of the solar shutters 210, 220, 230, and 240 when part thereof is unfolded may be lower than charging efficiency when they are not fully unfolded and may be higher than charging efficiency when they are not folded.

A degree at which each of the solar shutters 210, 220, 230, and 240 is unfolded, may be designated as the user input input into the input unit 800.

When the control condition regarding rain or snow, i.e., the intensity of rain or snow or the quantity of rain or snow detected by the rainsplash sensor 420 is equal to or greater than a predetermined value, an operation corresponding to the control condition may include controlling at least one among the solar shutters 210, 220, 230, and 240 to be unfolded, by using the controller 300. Also, in this case, the unfolded solar shutters 210, 220, 230, and 240 may be designated as user input input into the input unit 800. Also, a degree at which each of the solar shutters 210, 220, 230, and 240 is unfolded, may be designated as the user input.

When a control condition regarding humidity, i.e., humidity around the vehicle detected by the hygrometer 900 is equal to or greater than power generation limiting humidity, an operation corresponding to the control condition may include not unfolding the solar shutters 210, 220, 230, and 240 by using the controller 300.

When the control condition regarding humidity, i.e., humidity around the vehicle detected by the hygrometer 900 is less than the power generation limiting humidity, the operation corresponding to the control condition may include controlling the solar shutters 210, 220, 230, and 240 to be fully unfolded, by using the controller 300. According to the current embodiment of the present invention, even in this case, the controller 300 may control only part of the front window solar shutter 210 to be folded, so as to obtain the driver's field of vision during driving. According to the current embodiment of the present invention, in this case, the side window solar shutters 220 may not be unfolded so that the side mirrors may be used.

Also, even in this case, if the vehicle is being reversed, the controller 300 may control the rear window solar shutter 220 to not be folded, so as to obtain the drivers' field of vision during driving. According to the current embodiment of the present invention, in this case, the side window solar shutters 220 may not be unfolded so that the side mirrors may be used.

When the control condition regarding humidity, i.e., humidity around the vehicle detected by the hygrometer 900 is less than the power generation limiting humidity, the operation corresponding to the control condition may include controlling only part of the solar shutters 210, 220, 230, and 240 to be unfolded, by using the controller 300.

When the control condition regarding humidity, i.e., humidity around the vehicle detected by the hygrometer 900 is less than the power generation limiting humidity, the operation corresponding to the control condition may include controlling at least one among the solar shutters 210, 220, 230, and 240 to be unfolded, by using the controller 300. Also, in this case, the unfolded solar shutters 210, 220, 230, and 240 may be designated as the user input input into the input unit 800. Also, a degree at which each of the solar shutters 210, 220, 230, and 240 is unfolded, may also be designated as the user input.

When the control condition regarding light according the current embodiment of the present invention, i.e., illuminance detected by the illuminance sensor 410 is equal to or greater than power generation limiting illuminance, the operation corresponding to the control condition may include controlling the solar shutters 210, 220, 230, and 240 to be fully folded, by using the controller 300. According to the current embodiment of the present invention, even in this case, the controller 300 may control only part of the front window solar shutter 210 to be folded, so as to obtain the driver's field of vision during driving. According to the current embodiment of the present invention, in this case, the side window solar shutters 220 may not be unfolded so that the side mirrors may be used.

Also, even in this case, if the vehicle is being reversed, the controller 300 may control the rear window solar shutter 220 to not be folded, so as to obtain the driver's field of vision during driving. According to the current embodiment of the present invention, in this case, the side window solar shutters 220 may not be unfolded so that the side mirrors may be used.

When the control condition regarding light, i.e., illuminance detected by the illiminance sensor 410 is less than the power generation limiting illuminance, an operation corresponding to the control condition may include controlling the solar shutters 210, 220, 230, and 240 to not be unfolded, by using the controller 300. In this case, the controller 300 may determine that a parking place of the vehicle is indoor parking or underground parking. Also, according to the current embodiment of the present invention, when the controller 300 determines a case where illuminance detected by the illuminance sensor 410 is less than the power generation limiting illuminance, the controller 300 may determine whether illuminance is maintained to be less than the power generation limiting illuminance for a predetermined amount of time. In this case, the controller 300 may determine that a driving place of the vehicle is a place that cannot be temporarily power-generated, such as a tunnel or an underpass. The controller 300 according to the current embodiment of the present invention may use the timer 600 so as to measure elapse of time.

When the control condition regarding light, i.e., illuminance detected by the illuminance sensor 410 is equal to or greater than the power generation limiting illuminance, an operation corresponding to the control condition may include controlling only part of the solar shutters 210, 220, 230, and 240 to be unfolded.

When the control condition regarding light, i.e., illuminance detected by the illuminance sensor 410 is equal to or greater than the power generation limiting illuminance, an operation corresponding to the control condition may include controlling at least one among the solar shutters 210, 220, 230, and 240 to be unfolded. Also, in this case, the unfolded solar shutters 210, 220, 230, and 240 may be designated as the user input input into the input unit 800. Also, a degree at which each of the solar shutters 210, 220, 230, and 240 is unfolded, may be designated as the user input.

When the control condition regarding a driving state according to the current embodiment of the present invention is a fully-parked state in which starting of the vehicle detected by the starting state sensor 450 is stopped and it is determined that the driver is in the vehicle or a parked state in which starting of the vehicle detected by the starting state sensor 450 is stopped and it is determined that the driver is outside the vehicle, an operation corresponding to the control condition may include controlling the solar shutters 210, 220, 230, and 240 to be fully unfolded, by using the controller 300.

According to the current embodiment of the present invention, it may be detected by an additional sensor (not shown) whether the driver is in the driver's vehicle.

Also, according to the current embodiment of the present invention, it may be determined whether the driver is in the driver's vehicle, based on whether a key for starting the vehicle is inserted into the vehicle. In this case, when the key for starting the vehicle is inserted into the vehicle, the controller 300 determines that the driver is in the vehicle, and when the key for starting the vehicle is inserted into the vehicle, it may be determined that the driver is not in the driver's vehicle.

Also, according to the current embodiment of the present invention, it may be determined whether the driver is in the driver's vehicle, based on a position of the key for starting the vehicle. In this case, the controller 300 may determine that the driver is in the vehicle, when the key for starting the vehicle is placed in the vehicle, and the controller 300 may determine that the driver is not in the vehicle, when the key for starting the vehicle is placed outside the vehicle.

According to the current embodiment of the present invention, even in this case, the controller 300 may control only part of the front window solar shutter 210 to be unfolded, so as to obtain the driver's field of vision during driving. According to the current embodiment of the present invention, in this case, the side window solar shutter 220 may not be unfolded so that the side mirrors may be used.

Also, even in this case, if the vehicle is being reversed, the controller 300 may control the rear window solar shutter 220 to not be unfolded, so as to obtain the driver's field of vision during driving. According to the current embodiment of the present invention, in this case, the side window solar shutters 220 may not be unfolded so that the side mirrors may be used.

When a control condition regarding the driving state is a temporarily-parked state in which starting of the vehicle detected by the starting state sensor 450 is performed and the vehicle does not operate and it is determined that the driver is in the vehicle or a driving state in which starting of the vehicle is performed and a stoppage time is less than a predetermined amount of time, an operation corresponding to the control condition may include controlling only part of the solar shutters 210, 220, 230, and 240 to be unfolded, by using the controller 300.

It may also be detected by the vehicle speed sensor 440 whether the vehicle according to the current embodiment of the present invention operates. Also, it may also be detected by the GPS 500 whether the vehicle according to the current embodiment of the present invention operates.

When it is detected by the starting state sensor 450 that the control condition regarding the driving state is a state in which the vehicle is temporarily stopped or driven, an operation corresponding to the control condition may include controlling at least one among the solar shutters 210, 220, 230, and 240 by using the controller 300. Also, in this case, the unfolded solar shutters 210, 220, 230, and 240 may be designated as the user input input into the input unit 800. Also, a degree at which each of the solar shutters 210, 220, 230, and 240 is unfolded, may be designated as the user input.

When a control condition regarding the remaining battery charge according to the current embodiment of the present invention, i.e., the remaining quantity of the battery charge detected by the battery charging state sensor 430 is equal to or less than a maximally-charged limit, an operation corresponding to the control condition may include controlling the solar shutters 210, 220, 230, and 240 to be fully unfolded, by using the controller 300. According to the current embodiment of the present invention, even in this case, the controller 300 may control only part of the front window solar shutter 210 to be unfolded, so as to obtain the driver's field of vision during driving. According to the current embodiment of the present invention, in this case, the side window solar shutters 220 may not be unfolded so that the side mirrors may be used.

Also, even in this case, if the vehicle is being reversed, the controller 300 may control the rear window solar shutter 220 to not be unfolded, so as to obtain the drivers' field of vision during driving. According to the current embodiment of the present invention, in this case, the side window solar shutters 220 may not be unfolded so that the side mirrors may be used.

When the control condition regarding the remaining battery charge according to the current embodiment of the present invention, i.e., the remaining quantity of the battery detected by the battery charging state sensor 430 is equal to or greater than the maximally-charged limit, an operation corresponding to the control condition may include controlling the solar shutters 210, 220, 230, and 240 to not be unfolded, by using the controller 300 or controlling only part of the solar shutters 210, 220, 230, and 240 to be unfolded. Also, in this case, the unfolded solar shutters 210, 220, 230, and 240 may be designated as the user input input into the input unit 800. Also, a degree at which each of the solar shutters 210, 220, 230, and 240 is unfolded, may be designated as the user input.

When the control condition regarding the remaining quantity of the battery according to the current embodiment of the present invention, i.e., the remaining quantity of the battery detected by the battery charging state sensor 430 is less than the maximally charged limit, the operation corresponding to the control condition may include controlling at least one among the solar shutters 210, 220, 230, and 240 to be unfolded, by using the controller 300. Also, in this case, the unfolded solar shutters 210, 220, 230, and 240 may be designated as the user input input into the input unit 800. Also, a degree at which each of the solar shutters 210, 220, 230, and 240 is unfolded, may be designated as the user input.

Charging efficiency of the solar shutters 210, 220, 230, and 240 according to the current embodiment of the present invention is increased as it becomes hotter. Also, as latitudes of the solar shutters 210, 220, 230, and 240 are lowered, their charging efficiency is increased. Also, as the frequency of use of a heater and/or an air conditioner is increased, the solar shutters 210, 220, 230 are required to be further charged.

When a control condition regarding a usage level of the heater and/or the air conditioner according to the current embodiment of the present invention, i.e., the usage level of the heater and/or the air conditioner determined by the controller 300 is increased to be equal to or greater than a predetermined setting value, an operation corresponding to the control condition may include controlling part or the whole of the solar shutters 210, 220, 230, and 240 to be unfolded, by using the controller 300.

Subsequently, the method for controlling the power generation type solar shutter will be further described with reference to FIG. 5.

The controller 300 detects that an event occurs (Operation S103).

The controller 300 determines whether the event satisfies a control condition (Operation S105).

If the event satisfies the control condition, the controller 300 controls the solar shutters 210, 220, 230, and 240 to perform an operation corresponding to the control condition satisfied by the event (Operation S107).

As described above, the present invention provides an apparatus and method for controlling a power generation type solar shutter, whereby the power generation type solar shutter is operated and the vehicle can be efficiently charged in consideration of the environment around a vehicle, a state of the vehicle or a charging state of the battery therein.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for controlling a power generation type solar shutter, comprising:
storing a control condition and an operation corresponding to the control condition;
detecting that an event occurs; and
if the event satisfies the control condition, controlling the solar shutter that performs a charging function for a vehicle based on the operation corresponding to the control condition,
wherein the control condition comprises at least one selected from the group consisting of: humidity, rain, snow, light, a driving state, the remaining battery charge, seasons, latitude, and a usage level of a heater and/or an air conditioner.

2. The method as set forth in claim 1, wherein the solar shutter that performs a charging function is at least one selected from the group consisting of: a front window solar shutter, a rear window solar shutter, side window solar shutters, and a sunroof solar shutter.

3. The method as set forth in claim 2, wherein, if a control condition regarding humidity, that is, humidity around the vehicle, is equal to or greater than power generation limiting humidity, an operation corresponding to the control condition regarding humidity comprises not unfolding the solar shutter, and
if a control condition regarding humidity, that is, humidity around the vehicle, is less than the power generation limiting humidity, an operation corresponding to the control condition regarding humidity comprises unfolding part or the entirety of the solar shutter.

4. The method as set forth in claim 2, wherein, if a control condition regarding rain or snow, that is, an intensity of rain or snow or the quantity of rain or snow is equal to or greater than a predetermined value, an operation corresponding to the control condition regarding rain or snow comprises not unfolding the solar shutter, and
if a control condition regarding rain or snow, that is, an intensity of rain or snow or the quantity of rain or snow is less than a predetermined value, an operation corresponding to the control condition regarding rain or snow comprises unfolding part or the entirety of the solar shutter.

5. The method as set forth in claim 2, wherein, if a control condition regarding light, that is, illuminance around the vehicle is equal to or greater than power generation limiting illuminance, an operation corresponding to the control condition regarding light comprises unfolding part or the entirety of the solar shutter, and
if a control condition regarding light, that is, illuminance around the vehicle is less than the power generation limiting illuminance, an operation corresponding to the control condition regarding light comprises not unfolding the solar shutter.

6. The method as set forth in claim 2, wherein, if a control condition regarding a driving state is a fully-parked state in which starting of the vehicle is stopped and it is determined that a driver is in the vehicle or a parked state in which starting of the vehicle is stopped and it is determined that the driver is outside the vehicle, an operation corresponding to the control condition comprises fully unfolding the solar shutter, and
if a control condition regarding a driving state is a temporarily-parked state in which starting of the vehicle is performed and the vehicle does not operate and it is determined that the driver is in the vehicle or a driving state, an operation corresponding to the control condition comprises unfolding only part of the solar shutter.

7. An apparatus for controlling a power generation type solar shutter, comprising:
a solar shutter unit comprising at least one solar shutter that performs a charging function for a vehicle;
a storage unit in which a control condition and an operation corresponding to the control condition are stored; and
a controller detecting that an event occurs,
wherein, if the controller determines that the event satisfies the control condition, the controller controls the solar shutter that charges the vehicle to be unfolded based on the operation corresponding to the control condition, and
the control condition comprises at least one selected from the group consisting of humidity, rain, snow, light, a driving state, the remaining battery charge, seasons, latitude, and a usage level of a heater and/or an air conditioner.

8. The apparatus as set forth in claim 7, wherein the solar shutter unit comprises at least one selected from the group consisting of a front window solar shutter, a rear window solar shutter, side window solar shutters, and a sunroof solar shutter.

9. The apparatus as set forth in claim 8, wherein each solar shutter of the solar shutter unit comprises an on/off button, and a solar shutter comprising an on/off button in an off state is not controlled by the controller even if the event satisfies the control condition.

10. The apparatus as set forth in claim 8, further comprising a hygrometer that detects humidity around the vehicle,
wherein, if a control condition regarding humidity, that is, humidity around the vehicle is equal to or greater than power generation limiting humidity, an operation corresponding to the control condition regarding humidity comprises not unfolding the solar shutter, and
if a control condition regarding humidity, that is, humidity around the vehicle is less than the power generation limiting humidity, an operation corresponding to the control condition regarding humidity comprises unfolding part or the entirety of the solar shutter.

11. The apparatus as set forth in claim 8, further comprising a rainsplash sensor that detects an intensity of rain or snow or the quantity of rain or snow,
wherein the controller determines whether the event satisfies the control condition based on the intensity of rain or snow or the quantity of rain or snow, and
if a control condition regarding rain or snow, that is, the intensity of rain or snow or the quantity of rain or snow, is equal to or greater than a predetermined value, an operation corresponding to the control condition regarding rain or snow comprises not unfolding the solar shutter, and
if a control condition regarding rain or snow, that is, the intensity of rain or snow or the quantity of rain or snow is less than a predetermined value, an operation corresponding to the control condition regarding rain or snow comprises unfolding part or the entirety of the solar shutter.

12. The apparatus as set forth in claim 8, further comprising an illuminance sensor that detects illuminance around the vehicle,
wherein the controller determines whether the event satisfies the control condition based on illuminance detected by the illuminance sensor, and
if a control condition regarding light, that is, illuminance around the vehicle is equal to or greater than power generation limiting illuminance, an operation corresponding to the control condition regarding light comprises unfolding part or the entirety of the solar shutter, and
if a control condition regarding light, that is, illuminance around the vehicle is less than the power generation limiting illuminance, an operation corresponding to the control condition regarding light comprises not unfolding the solar shutter.

13. The apparatus as set forth in claim 12, wherein, if the controller determines whether the event satisfies the control condition regarding light and illuminance detected for a predetermined amount of time is maintained to be less than the power generation limiting illuminance, the controller controls the solar shutter to not be unfolded.

14. The apparatus as set forth in claim 8, wherein the controller detects a usage level of a heater and/or an air conditioner and determines whether the event satisfies the control condition, and
if a control condition regarding a usage level of the heater and/or air conditioner is increased to be equal to or greater than a predetermined setting value, an operation corresponding to the control condition comprises unfolding part or the entirety of the solar shutter.

15. The apparatus as set forth in claim 8, further comprising a driving state sensor that detects a driving state of the vehicle,
wherein the controller determines whether the event satisfies the control condition based on the driving state detected by the driving state sensor, and
if a control condition regarding the driving state is a fully-parked state in which starting of the vehicle is stopped and it is determined that a driver is in the vehicle or a parked state in which starting of the vehicle is stopped and it is determined that the driver is outside the vehicle, an operation corresponding to the control condition comprises fully unfolding the solar shutter, and
if a control condition regarding the driving state is a temporarily-parked state in which starting of the vehicle is performed and the vehicle does not operate and it is determined that the driver is in the vehicle or a driving state, an operation corresponding to the control condition comprises unfolding only part of the solar shutter.

16. The apparatus as set forth in claim 15, wherein, if the driving state sensor detects that the vehicle is in the driving state, the controller controls the front window solar shutter to not be fully unfolded, regardless of whether the event satisfies the control condition.

17. The apparatus as set forth in claim 15, wherein, if the driving state sensor detects that the vehicle is being reversed, the controller controls the rear window solar shutter to not be fully unfolded, regardless of whether the event satisfies the control condition.

18. The apparatus as set forth in claim 15, wherein, if the driving state sensor detects that the vehicle is being reversed or in the driving state, the controller controls the side window solar shutters to not be unfolded, regardless of whether the event satisfies the control condition.

19. The apparatus as set forth in claim 8, further comprising a battery charging state sensor that detects the remaining battery charge of the vehicle,
wherein the controller determines whether the event satisfies the control condition, based on the remaining battery charge of the vehicle detected by the battery charging state sensor, and
if a control condition regarding the remaining battery charge of the vehicle is equal to or greater than a maximally-charged limit, an operation corresponding to the control condition regarding the remaining battery charge of the vehicle comprises controlling the at least one solar shutter to not be unfolded or controlling only part of the shutter to be unfolded, and
if a control condition regarding the remaining battery charge of the vehicle is less than the maximally-charged limit, an operation corresponding to the control condition regarding the remaining battery charge of the vehicle comprises controlling at least one solar shutter to be unfolded.

20. The apparatus as set forth in claim 8, wherein the controller is capable of controlling each solar shutter of the solar shutter unit regardless of whether the event satisfies the control condition.
